(19) United States
(12) Patent Application Publication
(10) Pub. No.: US 2007/0012926 A1
(43) Pub. Date: Jan. 18, 2007

(54) Display device with reduced number of wires and manufacturing method thereof

(75) Inventors: Song-mi Hong, Gyeonggi-do (KR); Kwang-chul Jung, Gyeonggi-do (KR); Nam-deog Kim, Gyeonggi-do (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/480,199

(22) Filed: Jun. 30, 2006

(30) Foreign Application Priority Data
Jun. 30, 2005 (KR) 2005-0058051

(51) Int. Cl. H01L 29/04

(52) U.S. Cl. 257/72

(57) ABSTRACT

A display device with a decreased number of electrical lines and a method of making such display device are presented. The display device includes: a plurality of thin film transistors electrically connected to data wiring, wherein the data wiring includes a data line and a data electrode; a partition wall formed on the thin film transistor and having a contact hole exposing the data wiring; and a cathode electrically connected to the data wiring through the contact hole.

### CROSS-REFERENCE TO RELATED APPLICATIONS

This application claims priority from Korean Patent Application No. 2005-0058051, filed on Jun. 30, 2005 in the Korean Intellectual Property Office, the disclosure of which is incorporated herein by reference.

### BACKGROUND OF INVENTION

1. Field of Invention

The present invention relates to a display device and a method of manufacturing the same, and more particularly, to a display device with reduced number of wiring.

2. Description of Related Art

Recently, organic light emitting diode (OLED) device has been attracting much attention and interest from the flat panel display industry. Some reasons for the attention and interest are advantages such as low power consumption, light weight, slim shape, wide viewing angle, and high-speed response, among others. OLEDs are generally categorized into a passive matrix type and an active matrix type according to the driving mode. The passive matrix type can be fabricated through a relatively simple manufacturing process, but has the disadvantage that power consumption rapidly increases with increase of the display area and resolution. Due to this disadvantage, the passive matrix type is applied mainly to a small-size display device. The larger display devices often use active matrix type OLEDs, which don't have as rapid of an increase in power consumption with size. Active matrix type OLEDs, however, require a complicated fabrication process.

An OLED substrate includes a plurality of drive thin film transistors. An anode electrode forming a pixel and a cathode electrode serving a reference voltage are formed on the thin film transistors. When a voltage is applied to both electrodes, positive holes and electrons combine in a layer between the electrodes to form excitons. These excitons emit light when transitioning to the ground state in a light-emitting layer that is located between the electrodes. The OLED displays the desired image by controlling the light emission.

In order to form a pixel, a typical OLED includes a switching transistor connected with a data line and a driver transistor connected to a voltage supply line. In addition, the OLED may include multiple compensation transistors for compensating for a data voltage or applying a reference voltage. However, each additional transistor requires a separate wiring to transmit its signal. This need for separate wiring increases the number of wirings, thereby complicating the fabricating process of the substrate and reducing the aperture ratio.

### SUMMARY OF THE INVENTION

Accordingly, the present invention provides a display device with fewer electrical lines than the conventional display device and a method of manufacturing the same.

Additional features of the invention will be apparent from the description below or may be learned by practicing of the invention.

In one aspect, the invention is a display device including: a plurality of thin film transistors electrically connected with a data wiring, the thin film transistors including a first thin film transistor and a second thin film transistor. The display device also includes a partition wall formed on at least a portion of the first thin film transistor and the second thin film transistor and having a contact hole exposing the data wiring, and a cathode electrically connected to the data wiring through the contact hole.

In yet another aspect, the invention is a display device including: a plurality of signal lines, a plurality of thin film transistors connected to the signal lines, a plurality of pixel electrodes electrically connected to the thin film transistors, a partition wall, and a common electrode. The partition wall partitions neighboring pixel electrodes and has a contact hole exposing a thin film transistor of the thin film transistors. The common electrode is electrically connected to the thin film transistor through the contact hole.

In yet another aspect, the invention is a display device including a plurality of thin film transistors and a common electrode. The thin film transistors are electrically connected to a data wiring. At least a portion of the common electrode contacts the data wiring.

The invention is also a display device including a plurality of thin film transistors electrically connected to a data wiring. A plurality of first electrodes are electrically connected to the thin film transistors. A second electrode is formed on at least two of the first electrodes, the second electrode being connected to the data wiring.

In yet another aspect, the invention is a display device including an insulating substrate, a plurality of thin film transistors formed on the insulating substrate and electrically connected to a data wiring, and an electrode formed on substantially the entire surface of the insulating substrate and electrically connected to the data wiring.

In yet another aspect, the invention is a display device including: a plurality of thin film transistors electrically connected to a data wiring, a light-emitting layer formed on the thin film transistors, and a electrode formed on the light-emitting layer. The electrode is electrically connected to the data wiring. The light-emitting layer is capable of emitting light in response to a signal from the thin film transistors.

In yet another aspect, the invention is a display device including: an array of thin film transistors electrically connected to a data wiring, a partition wall formed on the thin film transistors, and an electrode formed on the partition wall. The partition wall divides the array of thin film transistors into pixel regions. The electrode is electrically connected to the data wiring.

In yet another aspect, the invention is a display device comprising: a pixel electrode, a driving transistor, a reference voltage transistor, a partition wall, and a common electrode. The driving transistor is electrically connected to the pixel electrode. The reference voltage transistor is capable of applying a reference voltage to the driving transistor. The partition wall, which is formed on the reference voltage transistor, has a contact hole exposing an electrode of the reference voltage transistor. The common electrode is electrically connected to the electrode through the contact hole.

In yet another aspect, the present invention is a method of manufacturing a display device. The method entails: forming a plurality of thin film transistors and a data wiring, forming a partition wall on the thin film transistors, and forming a cathode. The partition wall has a contact hole exposing the data wiring. The cathode is electrically connected to the data wiring through the contact hole.

It is to be understood that both the foregoing general description and the following detailed description are exemplary and explanatory and are intended to provide further explanation of the invention as claimed.

### BRIEF DESCRIPTION OF THE DRAWINGS

The above and/or other aspects and advantages of the present invention will become apparent and more readily appreciated from the following description of the exemplary embodiments, taken in conjunction with the accompanying drawings, in which:

FIG. 1 is a sectional view of a display device according to a first embodiment of the invention;

FIGS. 2A, 2B, and 2C explain a manufacturing method of the display device according to the first embodiment of the invention;

FIG. 3 schematically illustrates a display device according to a second embodiment of the invention;

FIG. 4 is a sectional view taken along the line IV-IV in FIG. 3;

FIG. 5 is a sectional view taken along the line V-V in FIG. 3;

FIG. 6 is an equivalent circuit diagram for the pixels according to the second embodiment of the invention; and

FIG. 7 is an equivalent circuit diagram for the pixels according to a third embodiment of the invention.

### DETAILED DESCRIPTION OF THE INVENTION

Reference will now be made in detail to the embodiments of the present invention, examples of which are illustrated in the accompanying drawings, wherein like reference numerals refer to like elements throughout. The embodiments are described below by referring to the figures.

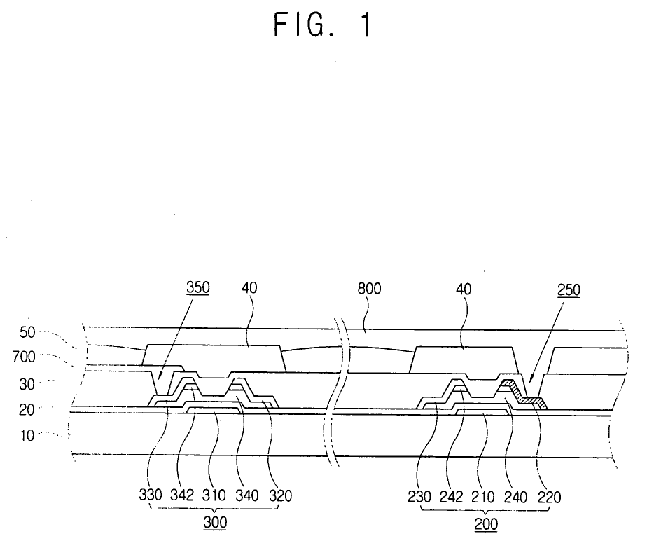

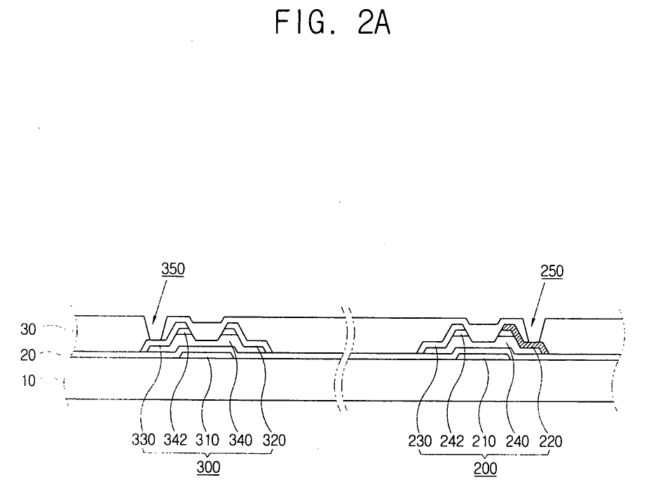

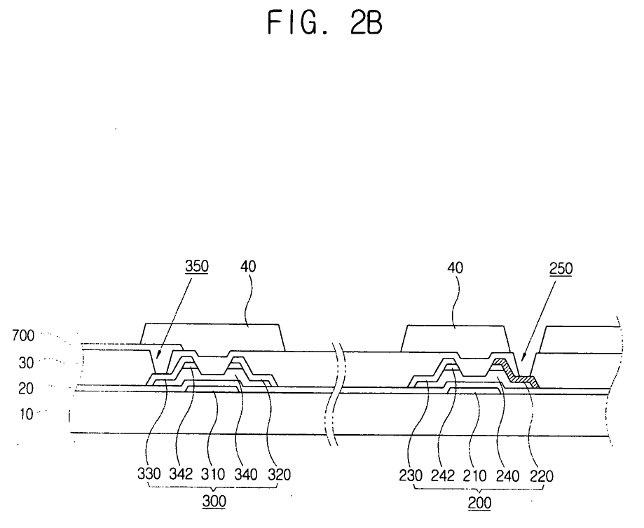

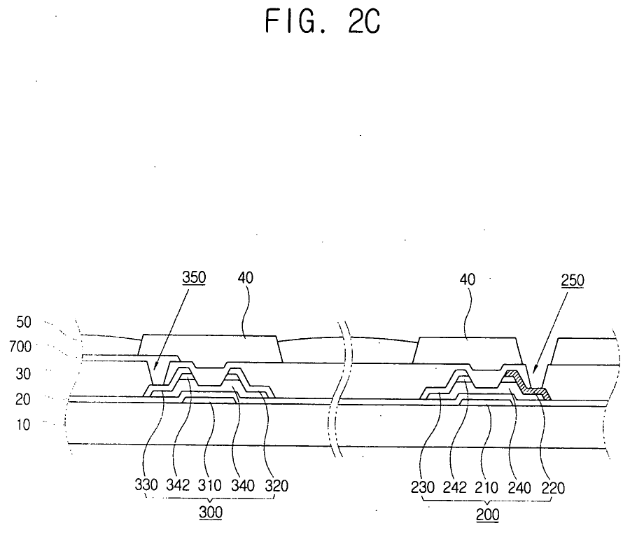

FIG. 1 is a sectional view of a display device according to a first embodiment of the invention. FIG. 2 illustrates a manufacturing method for the display device of FIG. 1. Although the display device of this embodiment will be described as an organic light emitting diode (OLED), this is not a limitation of the invention and the inventive concept may be adapted to other types of display device.

As shown in the figures, the display device includes a substrate 10 formed of an insulation material such as glass, quartz, ceramics or plastics, and a first and second thin film transistors (TFT) 200 and 300 formed on the substrate 10. The first TFT 200 has a gate electrode 210, a drain electrode 220, and a source electrode 230. Similarly, the second TFT 300 has a gate electrode 310, a drain electrode 320, and a source electrode 330. The drain electrodes 220, 320 and the source electrodes 230, 330 are herein collectively referred to as “data electrodes.” The first TFT 200 includes a partition wall 40 exposing a drain electrode 220, and a cathode electrically connected with the exposed drain electrode 220. In addition, the second TFT 300 includes a pixel electrode electrically connected with a source electrode 330 and a light-emitting layer 50 formed on the pixel electrode.

As used herein, the term “gate wiring” refers to metallic wiring including a gate line (not shown) for applying a gate signal and gate electrodes 210 and 310 of the TFTs 200 and 300. The term “data wiring” refers to metallic wiring including a data line (not shown) insulated from the gate wiring for applying a data signal and data electrodes of the TFTs 200 and 300. Depending on the embodiments, gate wiring and data wiring may also include additional elements.

The gate wiring may be formed in multiple layers with the material in each layer compensating for the drawback in the metal/alloy in another layer, thus obtaining a combination of desired physical properties. For example, the gate wiring may be constructed in two layers: a lower layer formed of aluminum or an aluminum alloy and an upper layer formed of chromium, molybdenum, molybdenum-tungsten, or molybdenum-tungsten nitride. The lower layer employs aluminum or aluminum alloys having a lower resistivity to improve signal resistance caused by the wiring resistance. As aluminum or aluminum alloys generally do not have a strong corrosion resistance against chemicals, a wiring employing only aluminum or its alloy is likely to experience oxidation and break. To compensate for this weakness, the upper layer is formed of a material with good corrosion resistance against chemicals, such as chromium, molybdenum, molybdenum-tungsten, or molybdenum-tungsten nitride. Recently, molybdenum (Mo), aluminum (Al), titanium (Ti), tungsten (W) or the like have been widely used as wiring materials.

A gate insulation film 20 is formed on the gate electrodes 210 and 310. The gate insulation film 20 is made of silicon nitride (SiNx) or the like, which covers the gate electrodes 210 and 310.

In addition, semiconductor layers 240, 340 are formed on the gate insulation film 20 where the gate electrodes 210 and 310 are placed. Ohmic contact layers 242, 342 are formed on the semiconductor layers 240, 340. The semiconductor layers 240, 340 are made of hydrogenated amorphous silicon or the like, and ohmic contact layers 242, 342 are made of n+ hydrogenated amorphous silicon doped with a high concentration of n-type impurity. Here, the respective ohmic contact layers 242, 342 are divided into two parts with the gate electrodes 210 and 310 placed in-between.

The drain electrodes 220, 320 and the source electrodes 230, 330, i.e. the data electrodes, are formed on the ohmic contact layers 242 and 342. Similarly to the gate wiring, the data wiring including these data electrodes may be formed in multiple layers with one layer compensating for the drawbacks of another layer. In an exemplary case where data wiring has a multi-layer structure, it is formed in three layers: molybdenum (Mo), aluminum (Al) and molybdenum (Mo). Here, the ohmic contact layers 242 and 342 function to reduce the contact resistance of the semiconductor layers 240 and 340 and of the source electrode 230 and 330 and the drain electrode 220 and 320.

A protective film 30 is formed on the data wiring including the TFTs 200 and 300. The protective film 30 is provided with a contact hole 250 exposing the drain electrode 220 of the first TFT 200 and a contact hole 350 exposing the source electrode 330 of the second TFT 300. The protective film 30 is formed of a material containing silicon nitride (SiNx). The contact holes 250 and 350 are preferably formed on the data electrodes that are part of the data wiring, but are not limited to being formed on the above-described drain electrode 220 or source electrode 330. That is, the contact holes may be formed in different places, depending on whether the drive voltage for driving the TFTs is applied through the source electrode or the drain electrode. In this embodiment, the contact holes 250 and 350 are formed in the source electrode 330 applying a data voltage to the pixel electrode, and in the drain electrode 220 receiving a negative voltage.

The pixel electrode is connected with the source electrode 330 of the second TFT 300 through the contact hole 350 formed in the protective film 30. The pixel electrode serves as an anode to provide positively-charged holes to the light-emitting layer 50.

The second TFT 300 is a driving transistor that applies a data voltage to the pixel electrode. That is, the second TFT 300 receives a data voltage through the drain electrode 320, which is a branch from the data wiring (not shown). The received data voltage is transmitted to the source electrode 330 through the semiconductor layer 340 when the gate electrode 310 is turned on, and finally transmitted to the pixel electrode to be applied to the light-emitting layer 50.

The partition wall 40 made of an organic material is formed on the TFTs 200 and 300. The partition wall 40 partitions neighboring pixel electrodes to prevent a short circuit from forming between the pixel electrodes. The partition wall 40 also partitions the respective pixel regions. Unlike the drain electrode 320 of the second TFT 300 connected with the pixel electrode, the drain electrode 220 of the first TFT 200 is not completely covered with the partition wall 40. The contact hole 250, which is formed by removing part of the protective film 30 and the partition wall 40, is positioned on the drain electrode 220. This contact hole 250 directly connects the drain electrode 220 of the first TFT 200 with the cathode so that the drain electrode 220 receives the voltage applied to the cathode.

The cathode is provided on the light-emitting layer 50, and is formed over substantially the entire surface of the substrate 10. The cathode is usually an opaque material such as aluminum (Al) or silver (Ag). The cathode is formed of a metallic material having a lower work function for smooth electron injection into the light-emitting layer 50, but may be formed of a transparent conductive material (as in the pixel electrode) in some embodiments. Where a transparent material is used for the cathode, light can be emitted in both directions of the substrate 100. Where the cathode is formed of an opaque material, the emitted light is directed primarily toward the substrate 10.

The first TFT 200 receives the TFT drive voltage from the cathode, not from a separate wiring formed on the substrate 10. This configuration eliminates the need for a separate wiring to drive the first TFT 200 as in a conventional display device. A common voltage, also referred to as a reference voltage is applied to the cathode, typically as the zero-volt reference point or a negative voltage. An OLED device requires many TFTs to produce images with the voltage applied to the light-emitting layer 50, or to apply a reference voltage of a desired level. Whenever an additional TFT is formed, it requires additional wiring to transmit the drive signals to the TFT. Furthermore, there is a particular TFT that requires a common voltage to be applied to the cathode, requiring yet a separate common voltage wiring to be formed.

In the display device according to the present invention, the voltage applied to the cathode can be used as the common voltage. Thus, it is not necessary to form a separate common voltage wiring on the substrate 10. The voltage received from the cathode does not have to be the common voltage and may be used as another type of voltage so long as the cathode is operably connected to the data electrode of the TFT.

Although not illustrated, the OLED may further include a protective film for protecting the cathode and an envelope member for preventing moisture and air from reaching the light-emitting layer 50.

Hereafter, a method of manufacturing the display device according to the first embodiment of the invention will be explained in reference to FIGS. 2a to 2c.

First, as shown in FIG. 2a, the TFTs 200 and 300 are formed on the substrate 10. The TFTs 200 and 300 can be made through any suitable known technique and the channel thereof is formed of amorphous silicon. Thereafter, the protective film 30 is formed on the TFTs 200 and 300. In a case where the protective film 30 is formed of silicon nitride, it may be formed through a chemical vapor deposition process. Then, the protective film 30 is etched through a photolithographic process to form the contact holes 350, 250 exposing the source electrode 330 of the second TFT 300 and the drain electrode 220 of the first TFT 200. After forming the contact hole 350, the pixel electrode is formed and connected to the source electrode 350. The pixel electrode may be formed in such a way that indium tin oxide (ITO) is vapor-deposited through a sputtering technique and patterned. The pixel electrode provides positively-charged holes to the light-emitting layer and thus is also referred to as an anode electrode.

Thereafter, as shown in FIG. 2b, an organic material is vapor-deposited on the TFTs 200 and 300 to form the partition wall 40. Then, the partition wall 40 is etched through a photolithographic process to form the contact hole 250 exposing the drain electrode 220 of the first TFT 200. The contact hole 250 on the drain electrode 220 is formed through two etching processes, i.e., one that forms the protective film 30 and another that forms the partition wall 40. The contact hole 250 allows the drain electrode 220 to connect to the cathode after the cathode is formed. The partition wall 40 is formed such that its cross-sectional area decreases with distance from the substrate 10 and positioned to separate the pixel electrodes.

Then, as shown in FIG. 2c, the light-emitting layer 50 is formed on the area in the pixel electrode that is not covered by the partition wall 40. The light-emitting layer 50 contains organic materials capable of emitting red light, blue light, green light, and the like, and the portions of the light-emitting layer 50 that emit colored light are formed in sequence on the array of pixel electrodes, so that each pixel has a color.

The organic material includes both high-molecular-weight and low-molecular-weight materials, and different techniques are used to form different materials. In the case of a high-molecular-weight material, the light-emitting layer 50 may employ an inkjet method whereby liquid is dropped through a nozzle, or a nozzle coating or spin coating technique using ink that is dissolved in a solvent. In the case of a low-molecular-weight material, a mask may be used for evaporating the respective colors.

In order to facilitate the movement of the positively-charged holes, a hole-injection layer or a hole-transfer layer may be further formed between the pixel electrode and the light-emitting layer 50. An electron-injection layer or electron-transfer layer may be further formed on the light-emitting layer 50.

Thereafter, the cathode is formed on the light-emitting layer 50, thereby completing the display device of FIG. 1.

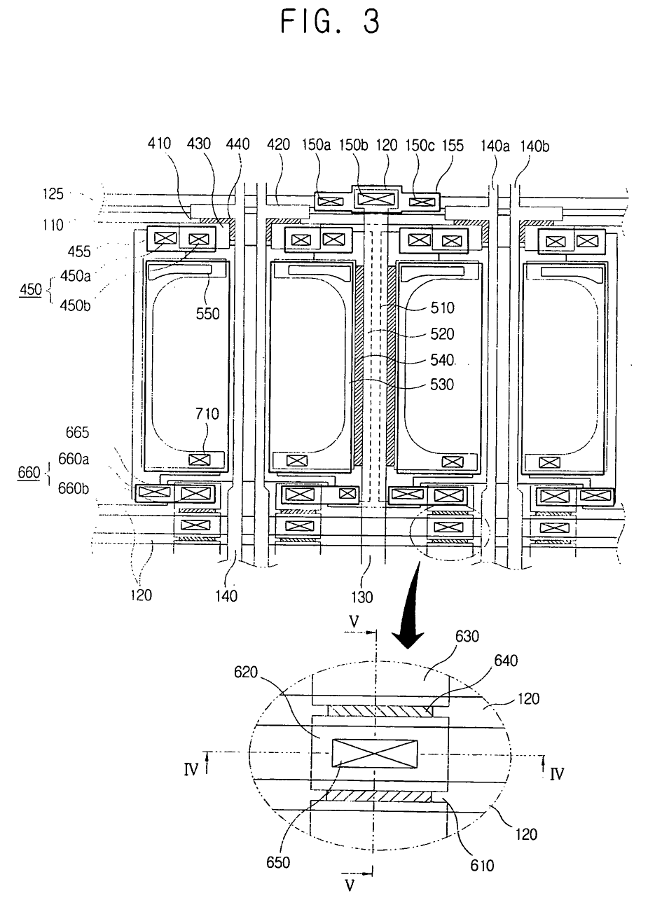

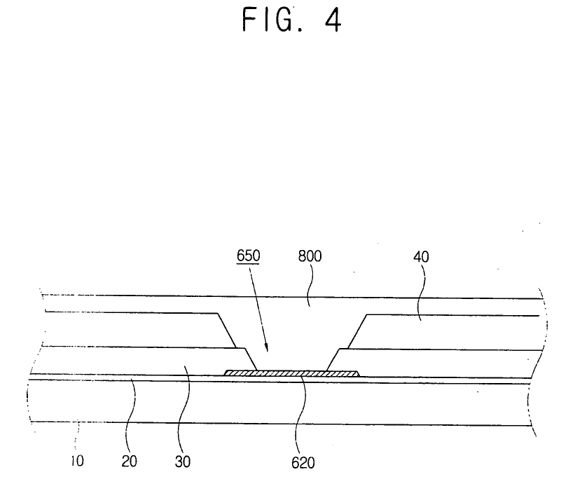

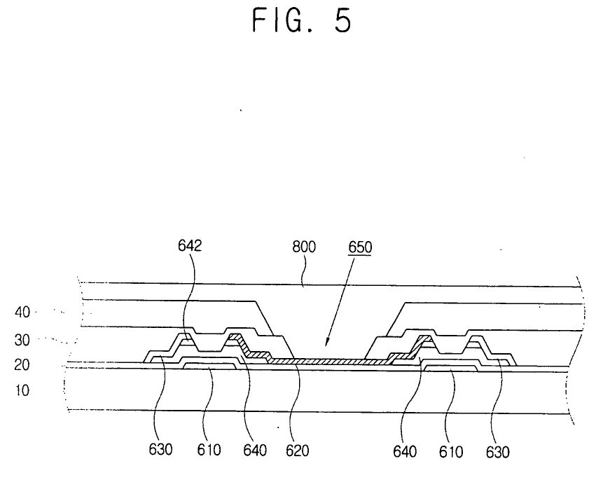

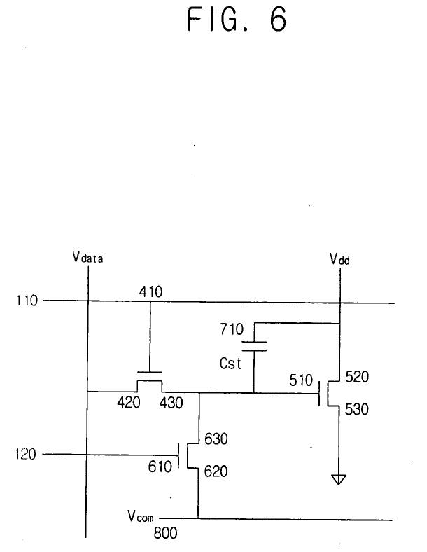

Hereafter, a second embodiment of the invention will be explained in reference to FIGS. 3 to 6. FIG. 3 shows the arrangement of a thin film transistor substrate according to the second embodiment of the invention. FIGS. 4 and 5 are sectional views taken along the lines IV-IV and V-V of FIG. 3, respectively. FIG. 6 is an equivalent circuit diagram for the pixels.

As illustrated in the figures, the display device of this embodiment includes gate wiring (elements 110, 120, 125, 410, 510 and 610 explained below), data wiring (elements 130, 140, 420, 520, 620, 430, 530 and 630 explained below), a switching transistor, a driving transistor, a recovery transistor, and a pixel electrode. The gate wiring, the data wiring, and a transparent material layer forming the pixel electrode and bridge electrodes 155, 455 and 665 are provided in different layers. For clear understanding of the invention, elements formed in a same layer are depicted with lines of the same thickness. If necessary, some elements formed in a lower layer are also shown although they do not appear on the actual substrate.

The gate wiring 110, 120, 125, 410, 510 and 610 includes a gate line 110 extending in a first direction, a recovery line 120 formed parallel to the gate line 110 for applying a recovery-on voltage, a drive voltage application line 125 for applying a drive voltage to a voltage supply line 130, and gate electrodes 410, 510 and 610 of respective transistors. The recovery line 120 is arranged in pairs between the pixel electrodes that neighbor each other in the first direction, and applies a recovery-on voltage to the gate electrode 610 of the recovery thin film transistor.

In this embodiment, data wiring includes a voltage supply line 130 intersecting the gate line 110, a data line 140 receiving a data voltage, and drain electrodes 420, 520 and 620 and source electrodes 430, 530 and 630 of the respective transistors.

The voltage supply line 130 and the data line 140 are formed parallel to each other and intersect the gate line to form pixel regions in a matrix. Each pixel region has a pixel electrode formed therein, and the voltage supply line 130 and the data line 140 are arranged between two pixel electrodes in an alternating manner. Thus, where pixels A, B, C, D, and E are arranged in the first direction, the supply line 130 would be placed between pixels A and B and between C and D. The data line 140 is placed between the pixels B and C and between D and E.

In general, one pixel electrode is connected to one voltage supply line and one data line. However, in this embodiment of the invention, a single voltage supply line 130 is shared by two pixel electrodes. That is, two pixel electrodes on either side of the voltage supply line 130 receive their drive voltage through a single voltage supply line 130. This reduced-line structure simplifies the fabrication process, and voltage-applying areas can be reduced to thereby alleviate electromagnetic interference. In addition, of the reduced-line structure increases the area of pixel electrode, thus improving the aperture ratio.

The drive voltage application line 125 and the drive voltage application line 130 are electrically interconnected through a first bridge electrode 155, which interconnects contact holes 150a and 150c and a contact hole 150b exposing the drive voltage application line 125 and the drive voltage application line 130 respectively. The first bridge electrode 155, and a second and third bridge electrodes 455 and 665 (which will be explained below) are formed typically of a transparent conductive material such as indium tin oxide (ITO), indium zinc oxide (IZO), amorphous indium tin oxide (a-ITO), amorphous indium tin oxide (a-IZO), and the like.

The data lines 140a and 140b are arranged in pairs between neighboring pixel electrodes. The data lines 140a and 140b are indirectly connected to their respective neighboring pixel electrodes to apply a data voltage. The arrangement of the data lines 140a and 140b is not limited to this embodiment. For example, the respective individual data lines may be arranged one by one between neighboring pixel electrodes instead of in pairs. However, regardless of the specific arrangement that is adopted, the switching transistor connected to the data lines 140a and 140b and the driving transistor connected to the voltage supply line 130 are electrically connected to each other.

The switching transistor includes a gate electrode 410 forming part of the gate line 110, a drain electrode 420 branched from the data lines 140a and 140b, a source electrode 430 separated from the drain electrode 420, a semiconductor layer 440 formed between the drain electrode 420 and the source electrode 430. Contact holes 450a and 450b are formed on the source electrode 430 of the switching transistor and the gate electrode 510 of the driving transistor, which are electrically connected to each other through a second bridge electrode 455.

The driving transistor is composed of a gate electrode 510 formed on a layer under the voltage supply line 130, a drain electrode 520 formed on the gate electrode 510 and forming part of the voltage supply line 130, a source electrode 530 separated from the drain electrode 520 and extending to the pixel region, and a semiconductor layer 540 formed between the drain electrode 520 and the source electrode 530. The semiconductor layer 540 extends in the same direction as the voltage supply line 130. The source electrode 530 is provided with a contact hole 550 for connection with the pixel electrode.

As shown in the enlarged view of FIG. 5, the recovery transistor includes a gate electrode 610 forming part of the recovery line 120, a drain electrode 620 and a source electrode 630 constituting the data wiring, and a semiconductor layer 640 formed between the drain electrode 620 and the source electrode 630. A single drain electrode 620 extends over two recovery lines 120, and a contact hole 650 is formed on the drain electrode 620.

FIG. 4 is a sectional view of the drain electrode 620 taken transversally along the line IV-IV in FIG. 3. As illustrated in FIG. 4, a gate insulation film 20 is formed on a substrate 10 and the drain electrode 620 constituting a data wiring is formed without a gate wiring. The gate insulation film 20 and part of the drain electrode 620 are covered with a protective film 30 and a partition wall 40. A contact hole 650 exposing the drain electrode 620 is formed on the drain electrode 620. The contact hole 650 is formed by removing portions of the protective film 30 and the partition wall 40. Through this contact hole 650, the drain electrode 620 is physically and electrically connected to the cathode. Conventionally, in order to apply a negative voltage to the drain electrode 620, a negative voltage application line is separately provided between the recovery lines 120. Thus, wiring becomes complicated and the aperture ratio is decreased. The embodiment of the invention avoids these problems by eliminating the need for a separate negative voltage application line. In the embodiment, the drain electrode 620 receives a negative voltage through the cathode. This simplifies the manufacturing process of a display device and at the same time the cathode can be effectively utilized.

FIG. 5 is a sectional view of the recovery thin film transistor taken vertically along the line V-V in FIG. 3. The source electrode 630 and the drain electrode 620 are formed across the gate electrodes 610 from each other. Here, the gate electrode 610 forms part of the recovery line 120. Two recovery thin film transistors share one drain electrode 620, which is provided with a contact hole 650. As shown in FIG. 4, the drain electrode 620 is directly connected with the cathode.

The pixel electrode is formed on the protective film 30 of the pixel area. The pixel electrode receives an image signal from the source electrode 530 via the connection through the contact hole 550. A contact hole 710 (see FIG. 3) is provided for a capacitor Cst and electrically connects the pixel electrode to the gate electrode 510 of the driving transistor. The capacitor Cst stores a voltage corresponding to the difference between the data voltage and the drive voltage, and maintains a constant voltage during a frame.

FIG. 6 is an equivalent circuit diagram for the pixels according to the second embodiment of the invention. Signal transmission between the transistors will be now explained in reference to FIG. 6.

First, a gate-on voltage applied to the gate line 110 is transmitted to the gate electrode 410 of the switching transistor. With the gate electrode 410 turned on, the data voltage from the data lines 140a and 140b flows toward the source electrode 430 from the drain electrode 420. The source electrode 430 of the switching transistor is electrically connected to the gate electrode 510 of the driving transistor through the contact holes 450a and 450b and the second bridge electrode 455.

the driving transistor adjusts the electric current between the drain electrode 520 and the source electrode 510 by using the gate electrode 510 that receives the data voltage. The voltage applied to the pixel electrode through the source electrode 530 corresponds to the difference between the data voltage and the drive voltage. The drain electrode 520 applies this voltage difference to the pixel electrode.

The capacitor Cst stores a voltage corresponding to the difference between the data voltage and the drive voltage such that the data voltage applied to the gate electrode 510 of the driving transistor and the current applied to the pixel electrode can be constantly maintained during one frame.

The recovery transistor applies a reverse voltage to the driving transistor in order to prevent a residual current from accumulating in the driving transistor. A constant drive voltage is applied to the drain electrode 520 of the driver transistor, possibly causing an accumulation of a residual current. This type of accumulation may interfere with proper transmission of the image signal to the pixel electrode. To preempt this type of problem, a reverse voltage is applied to the driving transistor to discharge the accumulated current. In other words, a reverse-biased voltage is applied to the current flowing through the driving transistor.

After a gate-on voltage is applied to the gate line 110, a recovery-on voltage is applied to the recovery line 120. When the recovery transistor is turned on by the recovery-on voltage, the reverse voltage applied from the cathode is transmitted to the gate electrode 510 of the driving transistor through the drain electrode 620 and the source electrode 630. Conventionally, a common voltage of about zero (0) volt is applied to the cathode. According to this embodiment of the invention, however, a negative voltage (i.e., a reverse voltage) is applied to the cathode. If the common voltage is a negative voltage, the voltage difference between the data voltage and the common voltage is increased. This increase in the voltage difference is advantageous as it allows expression of more colors.

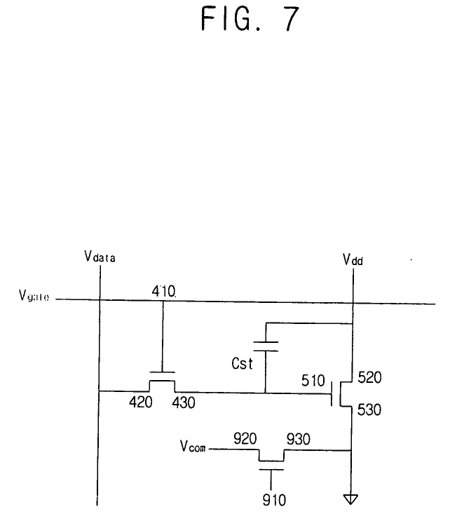

FIG. 7 is an equivalent circuit diagram for the pixels according to a third embodiment of the invention. As shown in FIG. 7, the circuits of the switching transistor and the driving transistor are configured in substantially the same manner as in the embodiment of FIG. 6. In this embodiment, however, the pixel is not provided with a recovery transistor for applying a negative voltage to the pixel electrode. In order to apply a stabilized data voltage to the light-emitting layer, the pixel of this embodiment includes a reference voltage transistor connected to the source electrode 530 of the driver transistor.

The reference voltage transistor applies the desired reference voltage to the source electrode 530 of the driving transistor before a data voltage is applied. The data voltage is applied to the light-emitting layer in a stable manner when the drive voltage Vdd serving as a reference voltage is constant. However, as the data voltage increases, the drive voltage may also increase. When this happens, the data voltage may not be appropriately applied to the light-emitting layer. The presence of a reference voltage transistor providing a reference voltage prevents the increase in the drive voltage with the data voltage and allows a constant voltage to be maintained in the terminals of the light-emitting layer. In this case, a reference voltage of zero (0) volt or an invariable reference voltage is applied to the reference voltage transistor. In this embodiment, the cathode is connected to the reference voltage transistor and a common voltage applied to the cathode is utilized. The cathode is electrically connected to the thin film transistor on the substrate and a separate wiring for reference-voltage application is not necessary.

As described above, the present invention provides a display device and a manufacturing method thereof, in which the wirings to be formed on a substrate can be reduced.

Although a few exemplary embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A display device comprising:
a plurality of thin film transistors electrically connected to data wiring, the thin film transistors including a first thin film transistor and a second thin film transistor and the data wiring including a data line and data electrodes;
a partition wall formed on at least a portion of the first thin film transistor and the second thin film transistor and having a contact hole exposing the data wiring; and
a cathode electrically connected to the data wiring through the contact hole.

2. The display device as set forth in claim 1, further comprising:
a pixel electrode electrically connected to the second thin film transistor; and
a light-emitting layer formed on the pixel electrode to emit light in response to a signal applied to the pixel electrode.

3. The display device as set forth in claim 1, wherein the partition wall partitions adjacent pixel electrodes.

4. A display device comprising:
a plurality of signal lines;
a plurality of thin film transistors connected to the signal lines;
a plurality of pixel electrodes electrically connected to the thin film transistors;
a partition wall partitioning neighboring pixel electrodes and having a contact hole exposing a thin film transistor of the thin film transistors; and
a common electrode electrically connected to the thin film transistor through the contact hole.

5. The display device as set forth in claim 4, wherein a negative voltage is applied to the common electrode.

6. The display device as set forth in claim 4, further comprising a light-emitting layer formed on the pixel electrode, the light-emitting layer capable of emitting light in response to a signal applied to the pixel electrode.

7. The display device as set forth in claim 4, wherein the thin film transistor is a recovery transistor for applying a reverse voltage to the pixel electrode, and the contact hole is formed on an electrode of the recovery transistor.

8. The display device as set forth in claim 7, wherein the electrode comprises one of a source electrode and a drain electrode.

9. The display device as set forth in claim 7, further comprising a recovery line for applying a recovery-on voltage to the recovery transistor.

10. The display device as set forth in claim 4, wherein the signal line comprises:
a gate line applying a gate-on voltage;
a data line applying a data voltage and extending substantially perpendicularly to the gate line; and
a voltage supply line for applying a drive voltage to the pixel electrode.

11. The display device as set forth in claim 10, wherein the voltage supply line extends substantially parallel to the data line.

12. The display device as set forth in claim 10, wherein the thin film transistors comprise:
a switching transistor provided at an intersection of the gate line and the data line; and
a driving transistor for driving the pixel electrode.

13. The display device as set forth in claim 9, further comprising a gate line applying a gate-on voltage, wherein the recovery line is provided on the same layer as the gate line.

14. The display device as set forth in claim 4, wherein the light-emitting layer comprises a polymer.

15. A display device comprising:
a plurality of thin film transistors electrically connected to data wiring, wherein the data wiring includes a data line and a data electrode; and
a common electrode, wherein at least a portion of the common electrode contacts the data wiring.

16. A display device comprising:
a plurality of thin film transistors electrically connected to a data wiring, wherein the data wiring includes a data line and a data electrode;
a plurality of first electrodes electrically connected to the thin film transistors; and
a second electrode formed on at least two of the first electrodes, the second electrode being connected to the data wiring.

17. A display device comprising:
an insulating substrate;
a plurality of thin film transistors formed on the insulating substrate and electrically connected to data wiring, wherein the data wiring includes a data line and a data electrode; and
a electrode formed on substantially the entire surface of the insulating substrate and electrically connected to the data wiring.

18. A display device comprising:
a plurality of thin film transistors electrically connected to data wiring, wherein the data wiring includes a data line and a data electrode;
a light-emitting layer formed on the thin film transistors, the light-emitting layer capable of emitting light in response to a signal from the thin film transistors; and
an electrode formed on the light-emitting layer and electrically connected to the data wiring.

19. A display device comprising:
An array of thin film transistors electrically connected to data wiring, wherein the data wiring includes a data line and a data electrode;
a partition wall formed on the thin film transistors, wherein the partition wall divides the array of thin film transistors into pixel regions; and
an electrode formed on the partition wall and electrically connected to the data wiring.

20. A display device comprising:
a pixel electrode;
a driving transistor electrically connected to the pixel electrode;
a reference voltage transistor for applying a reference voltage to the driving transistor;
a partition wall formed on the reference voltage transistor and having a contact hole exposing an electrode of the reference voltage transistor; and
a common electrode electrically connected to the electrode through the contact hole.

21. The display device as set forth in claim 20, wherein the electrode comprises one of a source electrode and a drain electrode.

22. The display device as set forth in claim 20, further comprising a light-emitting layer formed on the pixel electrode.

23. The display device as set forth in claim 22, wherein the light-emitting layer comprises a polymer.

24. A method of manufacturing a display device, the method comprising:
forming a plurality of thin film transistors and a data wiring;
forming a partition wall on the thin film transistors, the partition wall having a contact hole exposing the data wiring; and
forming a cathode electrically connected to the data wiring through the contact hole.

25. The method as set forth in claim 24, further comprising:
forming a pixel electrode electrically connected to the thin film transistor after forming the thin film transistor; and
forming a light-emitting layer on the pixel electrode.
